(19) United States
(12) Patent Application Publication
(10) Pub. No.: US 2026/0116676 A1
(43) Pub. Date: Apr. 30, 2026

(54) TRANSFER DEVICE, TRANSFER METHOD, AND PROCESSING METHOD

(71) Applicant: DISCO CORPORATION, Tokyo (JP)

(72) Inventor: Yusuke FUJII, Tokyo (JP)

(21) Appl. No.: 19/367,928

(22) Filed: Oct. 24, 2025

(30) Foreign Application Priority Data
Oct. 28, 2024 (JP) 2024-188773

(51) Int. Cl. B65G 47/90; H01L 21/67; H01L 21/677; H01L 21/687

(52) U.S. Cl. CPC B65G 47/90; H10P 72/0604; H10P 72/3411; H10P 72/7602

(57) ABSTRACT

A transfer device includes: a cassette table; a support unit; a transfer unit; and a control unit as defined herein, the cassette includes a pair of side walls and a support portion as defined herein, and the control unit includes a storage unit configured to store correlation information indicating a correlation as defined herein, and a controller configured to control, based on the correlation information, the direction of the object to be transferred by at least one of the support unit or the transfer unit when the object to be transferred is loaded from the support unit into the cassette such that the amount of deflection of the object to be transferred decreases.

### CROSS-REFERENCE TO RELATED APPLICATIONS

This application is based on and claims priority under 35 USC 119 from Japanese Patent Application No. 2024-188773 filed on Oct. 28, 2024, the contents of which are incorporated herein by reference.

### TECHNICAL FIELD

The present disclosure relates to a transfer device for an object to be transferred, a method for transferring the object to be transferred, and a method for processing a workpiece.

### BACKGROUND ART

In a step of thinning a wafer when producing a semiconductor wafer, a back surface of the wafer is thinned by grinding, and then the wafer is sometimes loaded into a cassette having a support portion that supports an outer periphery of the wafer (for example, Patent Literature 1).

Patent Literature 1: JP2022-144939A

### SUMMARY OF INVENTION

Since the thinned wafer has lower rigidity, even if the outer periphery of the wafer is supported by the support portion of the cassette, a central portion of the wafer may be deflected downward as compared with the outer periphery of the wafer. In such a case, for example, when the wafer is unloaded from the cassette, it may be difficult to hold the wafer, or the wafer may be damaged when the wafer is unloaded.

The present disclosure provides a transfer device, a transfer method, and a processing method capable of reducing deflection of an object to be transferred in a cassette after the object to be transferred is loaded into the cassette.

According to an aspect of the present disclosure, there is provided a transfer device including:
a cassette table on which a cassette capable of accommodating an object to be transferred is placed;
a support unit configured to support the object to be transferred;
a transfer unit configured to load the object to be transferred supported by the support unit into the cassette; and
a control unit configured to control the support unit and the transfer unit, in which the cassette includes a pair of side walls facing each other, and a support portion that is provided on inner side surfaces of the pair of side walls and supports an outer periphery of the object to be transferred,
the control unit includes
   a storage unit configured to store correlation information indicating a correlation between information on a direction of the object to be transferred when the object to be transferred is supported by the support portion of the cassette and amount of deflection of the object to be transferred when the object to be transferred is supported by the support portion of the cassette, and
   a controller configured to control, based on the correlation information, the direction of the object to be transferred by at least one of the support unit or the transfer unit when the object to be transferred is loaded from the support unit into the cassette such that the amount of deflection of the object to be transferred decreases.

According to another aspect of the present disclosure, there is provided a transfer method for loading an object to be transferred into a cassette, the transfer method including:
a support step of supporting the object to be transferred; and
a transfer step of loading the object to be transferred supported in the support step into the cassette placed on a cassette table, in which
in the transfer step, based on correlation information indicating a correlation between information on a direction of the object to be transferred when the object to be transferred is supported by a support portion of the cassette and amount of deflection of the object to be transferred when the object to be transferred is supported by the support portion of the cassette, the object to be transferred is loaded into the cassette such that the amount of deflection of the object to be transferred decreases.

According to another aspect of the present disclosure, there is provided a processing method including:
a holding step of holding a workpiece;
a processing step of processing the workpiece held in the holding step;
a support step of supporting the workpiece processed in the processing step; and
a transfer step of loading the workpiece supported in the support step into a cassette placed on a cassette table, in which
in the transfer step, based on correlation information indicating a correlation between information on a direction of the workpiece when the workpiece is supported by a support portion of the cassette and amount of deflection of the workpiece when the workpiece is supported by the support portion of the cassette, the workpiece is loaded into the cassette such that the amount of deflection of the workpiece decreases.

### BRIEF DESCRIPTION OF DRAWINGS

FIG. 1 is a perspective view illustrating an example of a transfer device 1.

FIG. 2 is a perspective view illustrating a front surface of a wafer W in an embodiment.

FIG. 3 is a perspective view illustrating a back surface of the wafer W in the embodiment.

FIG. 4 is a perspective view illustrating an example of a cassette C.

FIG. 5 is a diagram illustrating the deflection when the wafer W is accommodated in the cassette C.

FIG. 6 is an example of correlation information 120a, and is a graph illustrating a relation between a direction of a crystal orientation of the wafer W and the deflection.

FIGS. 7A, 7B, 7C and 7D are examples of the correlation information 120a, and are maps illustrating the correlation between information on a direction of the wafer W including the direction of the crystal orientation and a direction of a grinding surface, sheet information including a direction of an attachment surface of a protective sheet and an attachment direction, and the amount of deflection of the wafer W.

FIG. 8 is a table illustrating another example of the correlation information 120a.

FIG. 9 is a flowchart illustrating an example of the processing in a transfer method in the embodiment.

FIG. 10 is a perspective view illustrating an example of a processing device 200.

FIG. 11 is a flowchart illustrating an example of the processing in a processing method in the embodiment.

### DESCRIPTION OF EMBODIMENTS

Hereinafter, a transfer device, a transfer method, and a processing method according to an embodiment of the present disclosure will be described with reference to the drawings.

First, the configuration of a transfer device 1 will be described.

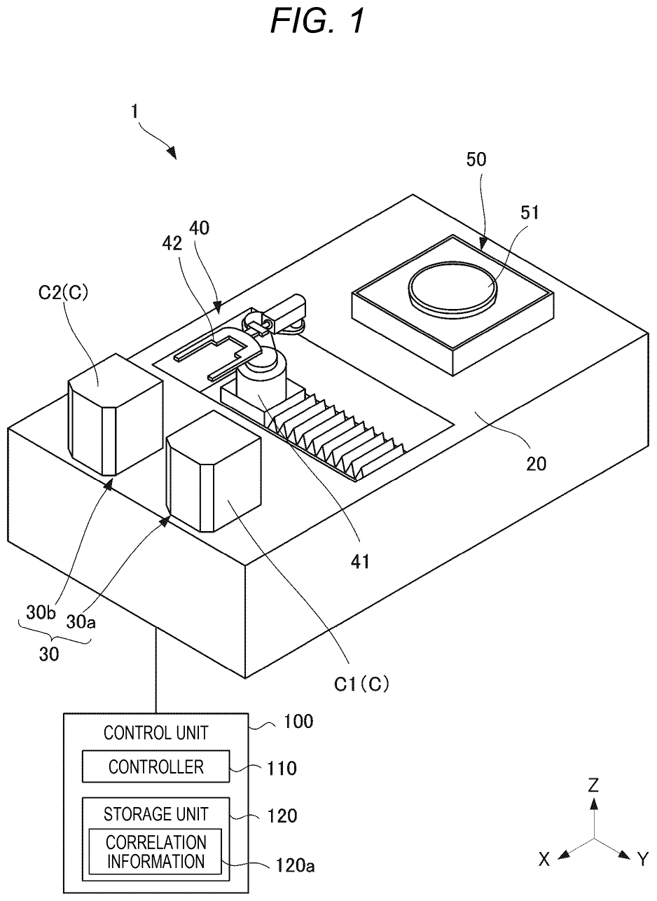

FIG. 1 is a perspective view illustrating an example of the transfer device 1 in the embodiment. The transfer device 1 is a device that transfers an object to be transferred supported by a support unit 50 to a cassette C that accommodates the object to be transferred. Here, the object to be transferred will be described.

### Object to be Transferred

The object to be transferred is, for example, substantially disk-shaped semiconductor device wafers, optical device wafers, or other wafers with substrates made of silicon (Si), silicon carbide (SiC), gallium nitride (GaN), gallium arsenide (GaAs), or the like. In the following description, the object to be transferred is referred to as a wafer W.

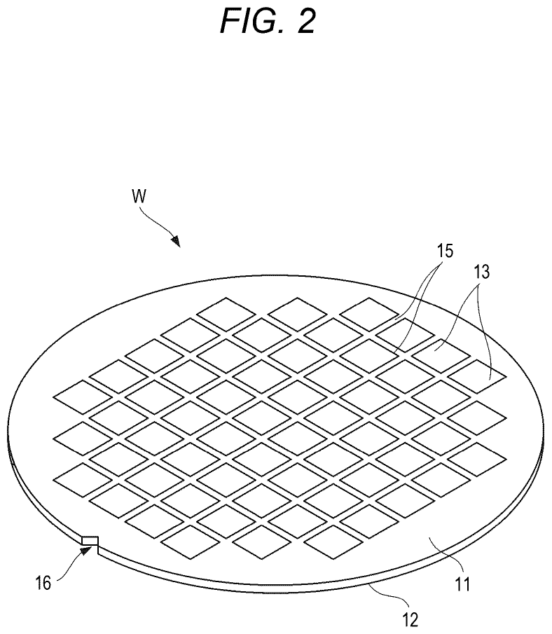

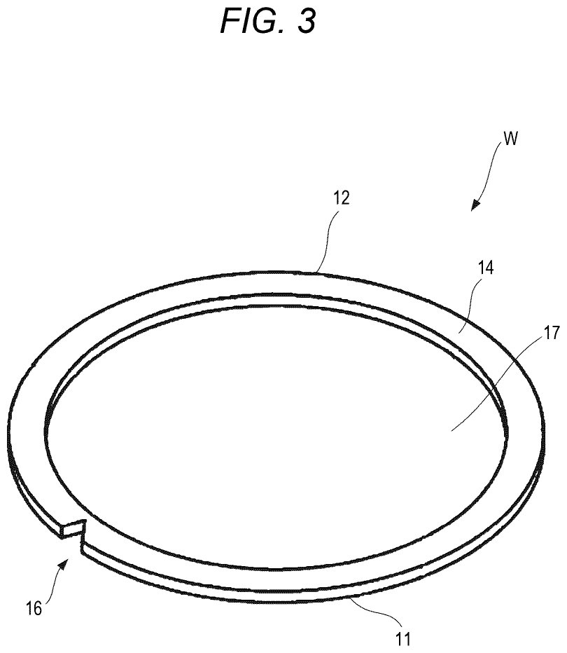

The wafer W in the embodiment is a wafer subjected to TAIKO grinding (registered trademark). FIG. 2 is a perspective view illustrating a front surface 11 of the wafer W, and FIG. 3 is a perspective view illustrating a back surface 12 of the wafer W. The TAIKO grinding is a technique for grinding the back surface 12 of the wafer W having, on the front surface 11, a device region in which a plurality of devices 13 are formed, by grinding and thinning only an inner portion of the back surface 12 of the wafer W that corresponds to a device region inside an outer peripheral edge of the back surface 12 of the wafer W while leaving the outer peripheral edge. By the TAIKO grinding, an annular reinforcing portion 14 that functions as a reinforcing portion is formed at the outer peripheral edge of the wafer W. By forming the annular reinforcing portion 14, even after the inner portion of the wafer W is thinned, warping of the wafer W and cracks of the wafer W when the wafer W is transferred are prevented, for example.

On the front surface 11 of the wafer W, as illustrated in FIG. 2, a plurality of intersecting streets 15 are set as planned dividing lines, and a plurality of regions partitioned by the planned dividing lines are formed in a grid pattern. A device 13 such as an integrated circuit (IC), a large scale integrated circuit (LSI), or a micro electro mechanical system (MEMS) is formed in each of the partitioned regions.

The wafer W is provided with a notch 16 indicating a crystal orientation of the wafer W. That is, the crystal orientation of the wafer W can be determined by the position of the notch 16. An orientation flat may be provided instead of the notch 16.

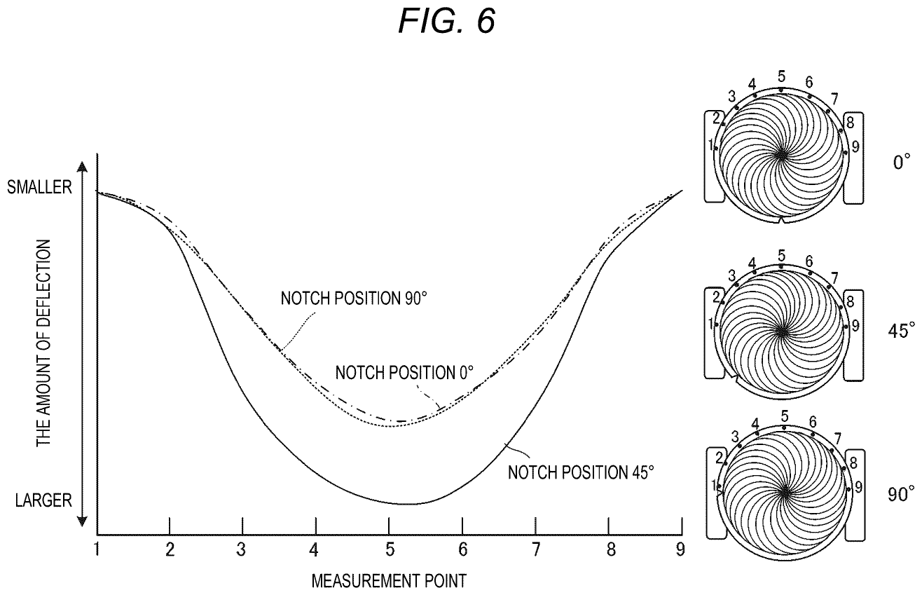

As illustrated in FIG. 3, the back surface 12 of the wafer W is formed with a circular recess 17 corresponding to the device region of the front surface 11 and the convex annular reinforcing portion 14 surrounding the circular recess 17. The circular recess 17 is a region to be ground when the wafer W is thinned. When the circular recess 17 is ground, radial saw marks, which are grinding marks, are formed as in the wafer W illustrated in FIG. 6, for example. As described above, the annular reinforcing portion 14 functions as a reinforcing portion in the outer peripheral edge of the wafer W.

A protective sheet (also referred to as a protective tape), which is a sheet for protecting the device 13, is attached to the front surface 11 of the wafer W. The protective sheet is an adhesive sheet that is formed in the shape of a disk having the same diameter as the wafer W, and includes a base layer made of a non-adhesive and flexible resin and an adhesive layer laminated on the base layer and made of an adhesive and flexible resin, the adhesive layer being attached to the front surface 11 of the wafer W. Alternatively, the protective sheet may be a sheet that does not include an adhesive layer, but includes only a base layer that is made of a thermoplastic resin and thermocompression bonded to the front surface 11 of the wafer W.

Returning to FIG. 1, the configuration of the transfer device 1 will be described. The transfer device 1 includes, as main components, a base 20, a cassette table 30, a transfer unit 40, a support unit 50, and a control unit 100. In the following description, an X-axis direction is a direction on a horizontal plane. A Y-axis direction is a direction orthogonal to the X-axis direction on the horizontal plane. A Z-axis direction is a direction orthogonal to the X-axis direction and the Y-axis direction.

The cassette table 30 is provided on one end side of the base 20 in the X-axis direction, and includes two placement spaces, a first placement space 30a and a second placement space 30b, which are aligned in the Y-axis direction. In the first placement space 30a, for example, a cassette C1 that accommodates a wafer W before being subjected to processing such as grinding is placed. In the second placement space 30b, for example, a cassette C2 that accommodates a ground wafer W transferred from the support unit 50, which will be described later, is placed. The cassette C1 and the cassette C2 can each accommodate a plurality of wafers W (for example, 25 wafers). In the following description, when the cassette C1 and the cassette C2 are not distinguished from each other, the cassette C1 and the cassette C2 are simply referred to as a cassette C.

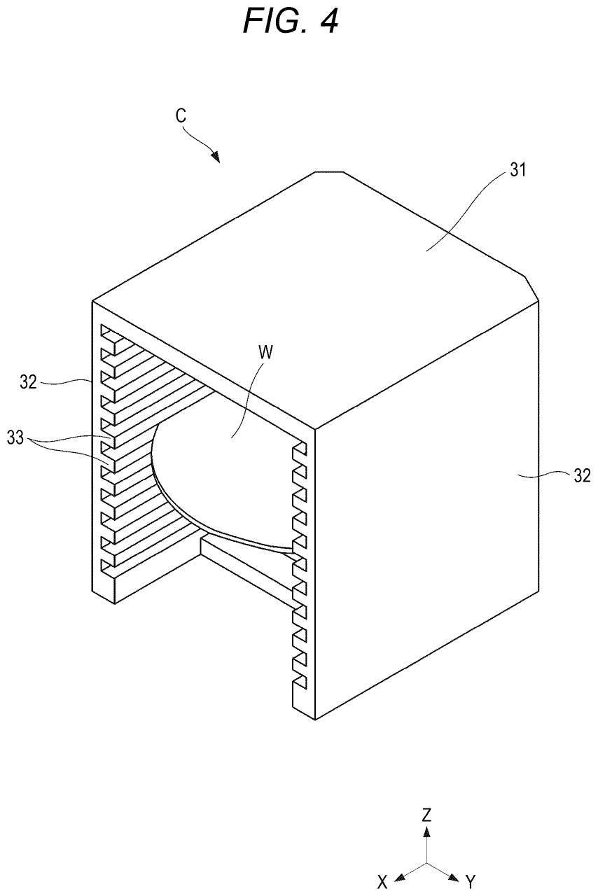

FIG. 4 is a perspective view illustrating an example of the cassette C in the embodiment. Although the cassette C can accommodate a plurality of wafers W as described above, FIG. 4 illustrates an example in which only one wafer W is accommodated for convenience. One side of the cassette C in the X-axis direction is opened such that the wafer W can be loaded and unloaded.

The cassette C includes a top plate 31 and a pair of side walls 32 extending downward from the top plate 31 in the Z-axis direction and facing each other in the Y-axis direction. On inner side surfaces of the pair of side walls 32, support portions 33 capable of supporting an outer periphery of the wafer W when the wafer W is accommodated in the cassette C extend in the X-axis direction. That is, when the wafer W is accommodated in the cassette C, both sides of the wafer W in the Y-axis direction are supported by the support portions 33 each extending in the X-axis direction. A plurality of support portions 33 are formed at predetermined intervals in an upper-lower direction in which the wafers W are stacked, making it possible to accommodate a plurality of wafers W in a horizontal state.

As illustrated in FIG. 1, the transfer unit 40 is provided adjacent to the cassette table 30, and transfers wafers into and out of the cassettes C1 and C2. The transfer unit 40 includes a pedestal 41 and a rotatable arm 42 supported on the pedestal 41. For example, the pedestal 41 is movable in the Y-axis direction. The direction in which the pedestal 41 can move may be any direction as long as the wafer W can be loaded and unloaded by the movement of the pedestal 41 and the operation of the arm 42. When the wafer W can be loaded and unloaded by the operation of the arm 42 alone, the pedestal 41 may be configured not to move. In the embodiment, for example, the transfer unit 40 can be moved in the Y-axis direction by a known ball screw type moving mechanism (not illustrated).

The transfer unit 40 transfers the wafer W between the cassette table 30 and the support unit 50 by the movement of the pedestal 41 and the operation of the arm 42. For example, the transfer unit 40 unloads the wafer W supported by a support table 51 of the support unit 50 and loads the wafer W into the cassette C2 placed in the second placement space 30b. Alternatively, the wafer W is unloaded from the cassette C1 placed in the first placement space 30a and loaded onto the support table 51.

The support unit 50 supports the wafer W to be loaded into the cassette C2. Specifically, the support unit 50 includes the support table 51 that supports the wafer W. For example, the wafer W ground by a grinding device (not illustrated) is transferred onto the support table 51. The support table 51 suctions and holds the transferred wafer W by operating a suction source (not illustrated). The support table 51 is rotatable around a Z-axis by a rotation drive mechanism (not illustrated). For example, when the wafer W is transferred from the support unit 50 and accommodated in the cassette C2, a direction of the wafer W can be adjusted by rotating the support table 51.

The control unit 100 controls each of the above components of the transfer device 1 to execute processing such as transferring the wafer W into the cassette C2. The control unit 100 is a computer including a controller 110 that performs various calculations, a storage unit 120 including a storage medium, and an input and output interface (not illustrated) that controls input and output of data between the inside and outside of the control unit 100. The controller 110 includes, for example, a microprocessor such as a central processing unit (CPU). The storage unit 120 includes a memory such as a hard disk drive (HDD), a read only memory (ROM), or a random access memory (RAM). The controller 110 performs various calculations based on predetermined programs stored in the storage unit 120. The controller 110 outputs, according to calculation results, various control signals to the above components via the input and output interface, and controls the transfer device 1.

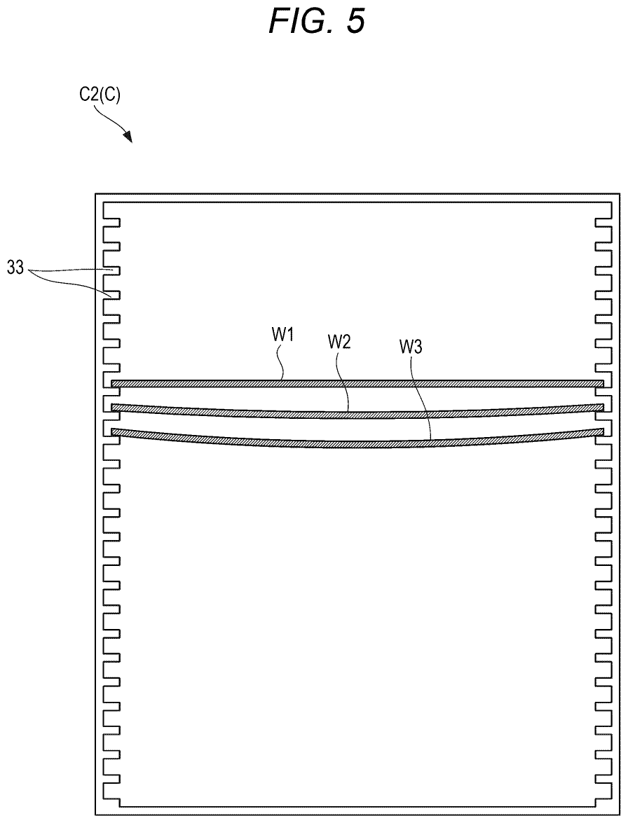

The controller 110 executes various programs stored in the storage unit 120. FIG. 5 is a diagram illustrating an example of deflection of a ground wafer W when the wafer W is accommodated in the cassette C2, and illustrates a state in which the wafer Wis accommodated in the cassette C2 as viewed from the front. When the wafer W is accommodated in the cassette C2, ideally there is no deflection, as in a wafer indicated by the reference numeral W1, for example. However, since a thinned wafer has lower rigidity, even if an outer periphery of the wafer is supported by the support portions 33 of the cassette C2, a central portion of the wafer may be deflected downward as compared with the outer periphery of the wafer as in wafers indicated by the reference numerals W2 and W3. In such a case, for example, when the wafer W is unloaded from the cassette C2, it may be difficult to hold the wafer W, or the wafer W may be damaged when the wafer W is unloaded. Therefore, in the embodiment, after the wafer W is loaded into the cassette C2, the controller 110 executes a program to reduce the deflection of the wafer W in the cassette C2.

Specifically, the controller 110 controls, based on correlation information 120a (hereinafter, also referred to as “correlation information 120a”) indicating a correlation between “information on a direction of a wafer” when the wafer W is supported by the support portions 33 of the cassette C2 and “the amount of deflection of a wafer” when the wafer W is supported by the support portions 33 of the cassette C2, the direction of the wafer W such that the amount of deflection of the wafer W decreases. The information on a direction of a wafer is an example of “information on a direction of an object to be transferred”in the embodiment.

The correlation information 120a is stored in advance in the storage unit 120. FIG. 6 is a graph illustrating an example of the correlation information 120a. In the example illustrated in FIG. 6, information on a direction of the crystal orientation of the wafer W is included as the information on a direction of a wafer. The direction of the crystal orientation may be defined based on any direction, and in the embodiment, as an example, the direction of the crystal orientation is defined based on a direction when the wafer W is accommodated in the cassette C2. For example, the direction in which the wafer W is accommodated in the cassette C2 is set to 0°, and the position of the notch 16, which indicates the crystal orientation when the wafer W is supported by the support portions 33, is defined as a direction or angle. The position of the notch 16 may be defined as, for example, 0°, 45°, or 90°. In the example illustrated in FIG. 6, as the correlation information 120a, a relation with the amount of deflection of the wafer W when the wafer W is supported by the support portions 33 with the notch 16 positioned at each of the directions of 0°, 45°, and 90°. The number of pieces of information on the direction of the crystal orientation is not limited to three, but may be two or more. For example, as the information on the direction of the crystal orientation increases, the accuracy of the information indicating the relation between the direction of the crystal orientation and the amount of deflection can be improved.

As can be seen from FIG. 6, when the notch 16 is supported by the support portions 33 at the direction of 45° with respect to the reference, the amount of deflection is the largest, and it can be seen that the amount of deflection is substantially the same between the case of 0° and the case of 90°. In the graph of FIG. 6, the vertical axis indicates the amount of deflection, and the horizontal axis indicates measurement points. The measurement points are nine points obtained by dividing an outer peripheral semicircle of the wafer W, both ends which are supported by the support portions 33, into eight equal parts. In this way, the amount of deflection of the wafer W varies depending on the direction of the crystal orientation.

The information on a direction of a wafer in the correlation information 120a may include information on whether a grinding surface of the wafer W is an upper surface or a lower surface of the wafer W. This is because the amount of deflection may vary depending on whether the grinding surface of the wafer W is the upper surface or the lower surface when the wafer W is accommodated in the cassette C2. The correlation information 120a may include sheet information indicating information on the protective sheet. The sheet information includes, for example, information on whether the front surface 11 of the wafer W to which the protective sheet is attached is the upper surface or the lower surface. The sheet information may also include information indicating an attachment direction of the protective sheet when the protective sheet is fixed to the wafer W.

The protective sheet is subjected to tension in the attachment direction of the protective sheet, and is subjected to a contraction force in a direction parallel to the attachment direction. A load of the wafer W itself (that is, the weight thereof) acts in a direction in which the wafer W is deflected. Therefore, it can be assumed that the tension corresponding to the attachment direction of the protective sheet may either promote or reduce the deflection of the wafer W depending on the direction of the grinding surface when the wafer W is accommodated in the cassette C2.

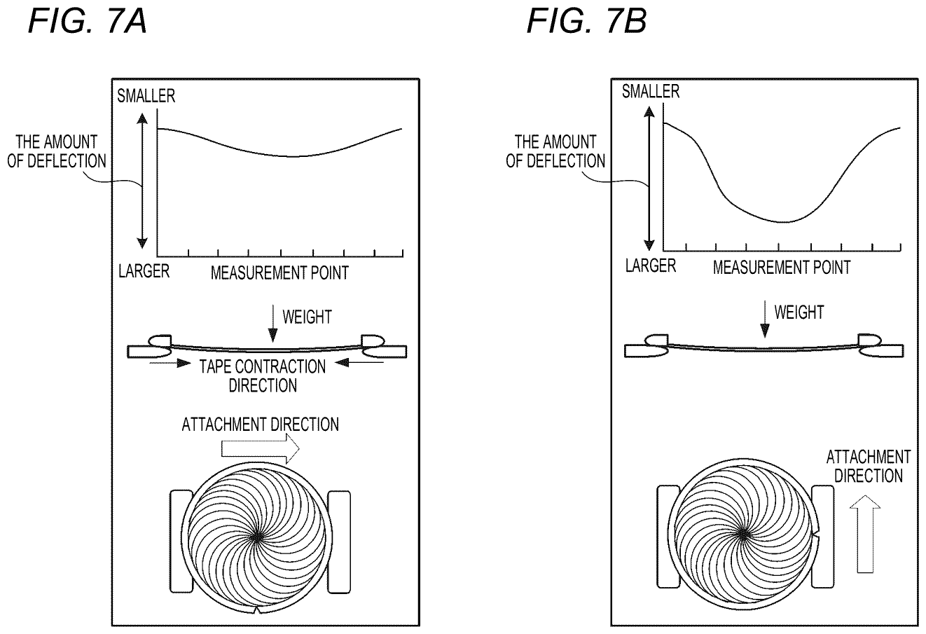

FIGS. 7A, 7B, 7C and 7D are maps illustrating examples of the correlation information 120a indicating a correlation between the information on the direction of the wafer W including the direction of the crystal orientation and the direction of the grinding surface, the sheet information including the direction of the attachment surface of the protective sheet and the attachment direction, and the amount of deflection of the wafer W. In FIGS. 7A, 7B, 7C and 7D, four examples (a) to (d) are illustrated. In the examples of FIG. 7, the wafers W illustrated on a lower side are examples in a top view in a state of being supported by the support portions 33. Among the four examples, in the examples of FIGS. 7A and 7B, saw marks indicating grinding marks extending radially from the central portion of the wafer W are illustrated. That is, in the examples of FIGS. 7A and 7B, it can be seen that the wafers W are accommodated in the cassette C2 with the back surface 12 facing upward. In other words, in the examples of FIGS. 7C and 7D, saw marks are not illustrated, and therefore, it can be seen that the wafers W are accommodated in the cassette C2 with the front surface 11 to which the protective sheet is fixed facing upward.

More specifically, for example, in the example of FIG. 7A, the attachment direction of the protective sheet, that is, the direction in which the protective sheet contracts is a direction orthogonal to the direction in which the wafer W is supported by the support portions 33 (the extending direction of the support portions 33) as indicated by a thick arrow. In the example of FIG. 7A, the grinding surface is the upper surface of the wafer W. In this case, the force in the contraction direction of the protective sheet acts against the weight of the wafer W. That is, the force that contracts the protective sheet acts to reduce the deflection of the wafer W. In the example of FIG. 7A, the position of the notch 16 indicating the direction of the crystal orientation is 0°.

On the other hand, for example, in the example of FIG. 7C, the information on the direction of the grinding surface is different from that in the example of FIG. 7A in that the grinding surface is the lower surface of the wafer W. That is, in the example of FIG. 7C, the surface on which the device 13 is formed and the protective sheet is attached faces upward. In this case, both the weight of the wafer W and the force that contracts the protective sheet act in the direction in which the wafer W is deflected. That is, the force that contracts the protective sheet acts to promote the deflection of the wafer W. Therefore, in the example of FIG. 7C, the amount of deflection is larger than that in the example of FIG. 7A.

In both the examples of FIGS. 7B and 7D, the attachment direction of the protective sheet, that is, the direction in which the protective sheet contracts is a direction parallel to the direction in which the wafer W is supported by the support portions 33 (the extending direction of the support portions 33), and the grinding surface is the upper surface in the example of FIG. 7B and the grinding surface is the lower surface in the example of FIG. 7D. In these cases, the directions of the grinding surfaces are different, but both have substantially the same amount of deflection. That is, it can be seen that the attachment direction of the protective sheet and the direction of the grinding surface in these cases have little influence on the amount of deflection of the wafer W.

That is, from the maps illustrated in FIGS. 7A, 7B, 7C and 7D, it can be seen that when the attachment direction of the protective sheet is orthogonal to the direction in which the wafer W is supported by the support portions 33, as in the example of FIG. 7A and the example of FIG. 7C, the amount of deflection of the wafer W is greatly affected by whether the grinding surface is the upper surface or the lower surface. As can be seen from the illustrated maps, it is preferable to control the direction of the wafer W and accommodate the wafer W in the cassette C2, as in the example of FIG. 7A in which the deflection of the wafer W is the smallest.

The information on the protective sheet may include, in addition to the attachment direction of the protective sheet, information on a draw-out direction which is a direction in which the protective sheet is drawn out when produced, and/or information on an orthogonal direction orthogonal to the draw-out direction. The “draw-out direction” is a direction in which the protective sheet is drawn out from a roll body around which the protective sheet is wound when the protective sheet is attached to the wafer W, and is a direction predetermined according to device specifications or the like. This draw-out direction is also referred to as a machine direction (MD). The orthogonal direction is a direction orthogonal to the MD direction, and is also referred to as a transverse direction (TD). In the following description, the draw-out direction is also referred to as the “MD direction”, and the orthogonal direction is also referred to as the “TD direction”.

The MD direction and the TD direction of the protective sheet may affect the amount of deflection of the wafer W. As a premise, the protective sheet is subjected to internal stress that contracts the protective sheet in both the MD direction and the TD direction, and the internal stress in the MD direction is usually larger than the internal stress in the TD direction. When the attachment direction of the protective sheet is the same as, for example, the MD direction or the TD direction, the amount of deflection of the wafer W may vary due to the influence of the MID direction or the TD direction. In particular, when the MD direction in which the internal stress is large and the attachment direction of the protective sheet are the same, the influence on the amount of deflection of the wafer W increases. Therefore, by storing the information on the MID direction and the TD direction in advance as the information on the protective sheet, an appropriate direction of the wafer W that reduces the amount of deflection of the wafer W can be determined.

In this way, the correlation information 120a is defined. Various conditions such as the attachment direction of the protective sheet described above are not limited to the above examples, and may be appropriately set by, for example, a person or an operator who uses the transfer device 1.

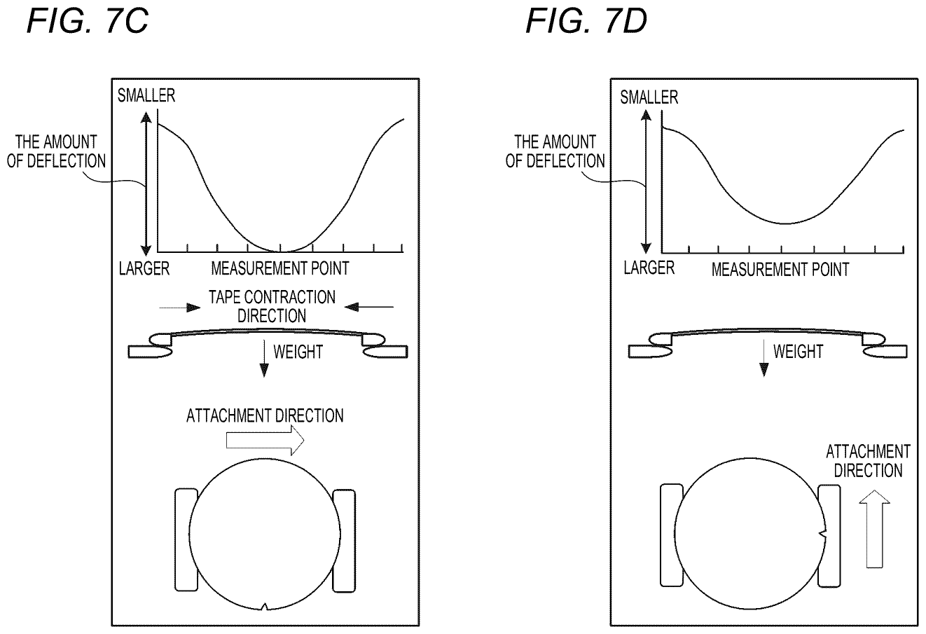

The correlation information 120a may be defined by putting the correlation information 120a into a table, in addition to the maps described above. FIG. 8 is a diagram illustrating an example of the table, and includes, for example, an ID, information on a direction of a wafer, sheet information, and information on the amount of deflection. The ID is identification information, and any ID such as “A001” may be set. The information on a direction of a wafer, the sheet information, and the information on the amount of deflection are associated with the ID.

The information on a direction of a wafer includes information on a direction of a crystal orientation and a direction of a grinding surface described above. The direction of the crystal orientation indicates the position of the notch 16, and for example, an angle is recorded when the direction in which the wafer W is accommodated in the cassette C2 is set to 0°.

The direction of the grinding surface indicates the direction of the grinding surface when a wafer is accommodated in the cassette C, and information on whether the grinding surface is an upper surface or a lower surface is recorded.

The sheet information includes information on an attachment surface of a protective sheet and information on an attachment direction. The direction of the attachment surface is the direction of the attachment surface of the protective sheet when a wafer is accommodated in the cassette C, and information on whether the attachment surface is an upper surface or a lower surface is recorded. The direction of the attachment surface is opposite to the direction of the grinding surface described above.

The attachment direction is the attachment direction of the protective sheet described above, and the attachment direction is recorded based on, for example, the direction in which the wafer W is supported by the support portions 33. For example, information such as “parallel” or “orthogonal” to the direction in which the wafer W is supported by the support portions 33 is recorded.

The amount of deflection is information indicating the amount of deflection of the wafer W measured under various conditions included in the information on a direction of a wafer and various conditions included in the sheet information, and for example, the maximum amount of deflection of the wafer W, a value obtained by averaging the amount of deflection at the measurement points, and the like are recorded.

The information on a direction of a wafer may include information on the MD direction and the TD direction described above (not illustrated).

When the wafer W is loaded into the cassette C from the support unit 50, the controller 110 controls the direction of the wafer W based on the correlation information 120a described above such that the amount of deflection of the wafer W decreases. Specifically, the controller 110 refers to the correlation information 120a stored in the storage unit 120 to specify the direction of the wafer W in which the amount of deflection of the wafer W is the smallest. For example, in the examples of the maps of FIGS. 7A, 7B, 7C and 7D described above, the amount of deflection is the smallest in the direction of the wafer W of FIG. 7A, and therefore the direction of the wafer W is specified. Then, the controller 110 controls at least one of the transfer unit 40 or the support unit 50 such that the wafer W has the specified direction.

For example, when the direction of the wafer W is controlled by the transfer unit 40, the controller 110 controls the pedestal 41 and the arm 42 of the transfer unit 40 to control the direction of the wafer W to the specified direction when the wafer W is loaded into the cassette C2 from the support unit 50. When the direction of the wafer W is controlled by the support unit 50, the direction of the wafer W is controlled by, for example, rotating the support unit 50 while the wafer W is supported by the support unit 50. Alternatively, the direction of the wafer W may be controlled by the support unit 50 and the transfer unit 40. For example, even if the direction of the wafer W is controlled by the support unit 50, the direction of the wafer W may be deviated when the wafer W is supported by the arm 42 of the transfer unit 40. In such a case, the transfer unit 40 may be controlled to adjust the deviation and load the wafer W into the cassette C2. Regardless of the means, the controller 110 only needs to be able to control, based on the correlation information 120a, the direction of the wafer W when the wafer W is loaded into the cassette C2 such that the amount of deflection of the wafer W decreases.

### Transfer Method

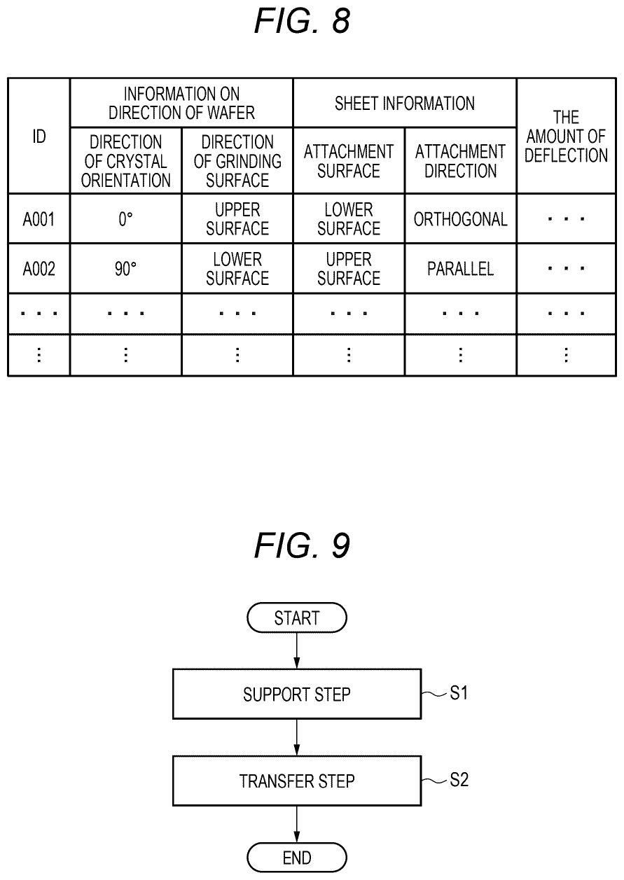

Next, a method for transferring the object to be transferred in the embodiment will be described. FIG. 9 is a flowchart illustrating an example of the transfer method. The transfer method includes a support step S1 and a transfer step S2 as processing. The processing of each step is executed by the controller 110.

In the support step S1, the controller 110 causes the support table 51 of the support unit 50 to support the ground wafer W transferred from, for example, a grinding device (not illustrated). That is, a suction source (not illustrated) is operated to suction and hold the transferred wafer W.

In the transfer step S2, the controller 110 loads the wafer W supported in the support step S1 into the cassette C2 placed on the cassette table 30. At this time, the controller 110 loads the wafer W into the cassette C2 based on the correlation information 120a described above such that the amount of deflection of the wafer W decreases. That is, the controller 110 refers to the correlation information 120a described above, specifies a direction of the wafer W in which the amount of deflection of the wafer W is the smallest, and controls the transfer unit 40 and the support unit 50 such that the wafer W has the specified direction.

In this way, the direction of the wafer W is controlled so as to reduce the amount of deflection of the wafer W based on a correlation between the “information on a direction of a wafer” and/or the “sheet information” and the “amount of deflection of a wafer” when the wafer W is supported by the support portions 33 of the cassette C2. Therefore, it is possible to reduce the deflection of the wafer W when the wafer W is accommodated in the cassette C2, and as a result, it is possible to reduce the possibility of inconveniences such as difficulty in holding the wafer W when the wafer W is unloaded from the cassette C2, or the wafer W coming into contact with the transfer unit 40 when the wafer Wis unloaded, resulting in damage to the wafer W. In the embodiment, since the correlation information 120a is stored in advance in the storage unit 120, it is possible to determine an appropriate direction of the wafer W by referring to the storage unit 120 and specifying a direction in which the amount of deflection of the wafer W decreases when the wafer W is accommodated in the cassette C2. Accordingly, for example, there is no need to determine a direction of the wafer W in which the amount of deflection decreases every time the wafer W is accommodated in the cassette C2.

### Modification

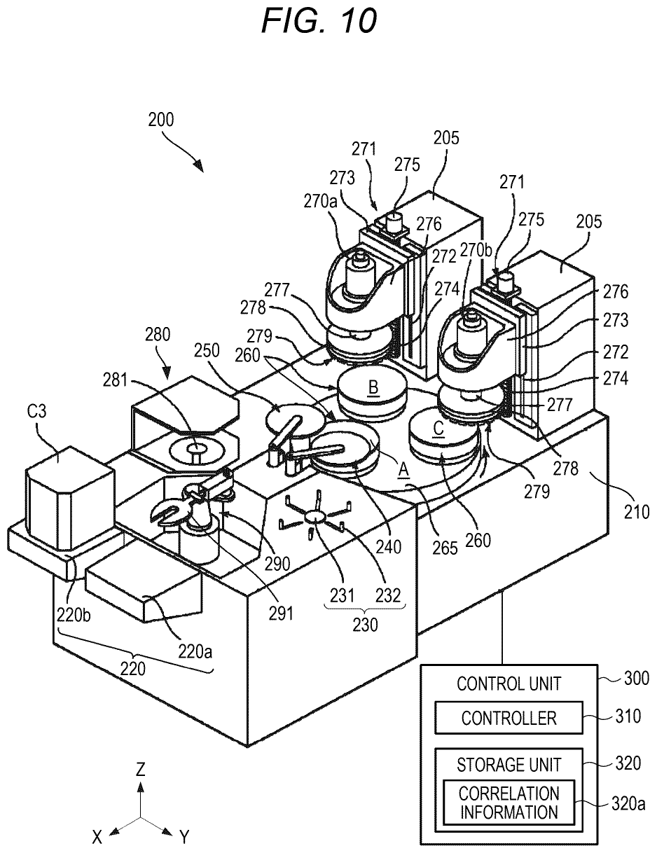

Next, a modification will be described. In the embodiment described above, the transfer device 1 has been described as an example of a device that is used, but another device may be used as long as the device can reduce the deflection of the wafer W when the wafer W is loaded into a cassette. For example, a processing device 200 having a grinding function of thinning the wafer W may be used. FIG. 10 is a perspective view illustrating an example of the processing device 200. The processing device 200 performs processing such as grinding on the wafer W as a workpiece. In the processing device 200, descriptions of components having the same functions as those of the transfer device 1 described above will be omitted or simplified.

The processing device 200 includes, as main components, a base 210, a cassette table 220, an alignment unit 230, a load unit 240, an unload unit 250, a holding table 260, a grinding unit 270, a cleaning unit 280, a transfer unit 290, and a control unit 300.

The cassette table 220 is provided on one end side of the base 210 in the X-axis direction, and includes two placement spaces, a first placement space 220a and a second placement space 220b, which are aligned in the Y-axis direction. A cassette C3 is placed in each of the first placement space 220a and the second placement space 220b, and for example, a plurality of unground and ground wafers W can be accommodated therein. In the example illustrated in FIG. 10, a cassette placed in the first placement space 220a is not illustrated. The configuration of cassettes placed in the first placement space 220a and the second placement space 220b may be the same as the configuration of the cassette C described above with reference to FIG. 4.

The alignment unit 230 is used to temporarily place the wafer W taken out from the cassette C3 and to align the center of the wafer W. The alignment unit 230 includes, for example, a table 231 that supports the wafer W and a plurality of pins 232 disposed around the table 231.

The load unit 240 suctions and holds the unground wafer W, which is aligned by the alignment unit 230, and loads the wafer W onto the holding table 260 located in a load and unload region A which will be described later. The load unit 240 has a suction pad (not illustrated) that suctions the wafer W.

The unload unit 250 suctions and holds the ground wafer W on the holding table 260 located in the load and unload region A which will be described later, unloads the wafer W from the holding table 260, and transfers the wafer W to the cleaning unit 280. The unload unit 250 has a suction pad (not illustrated) that suctions the wafer W.

The holding table 260 is a table that holds the wafer W and is disposed on a turntable 265. The turntable 265 is a disk-shaped table provided on an upper surface of the base 210, is rotatable about an axis parallel to the Z-axis direction, and is driven to rotate at a predetermined timing. On the turntable 265, for example, three holding tables 260 are disposed at equal intervals, for example, at a phase angle of 120°. The front surface 11 of the wafer W is placed on a holding surface of each of these three holding tables 260 and is held under suction. These three holding tables 260 are examples of a “holding unit” in the embodiment.

The holding table 260 is driven to rotate about the axis parallel to the Z-axis direction during grinding. The holding table 260 is sequentially moved to the load and unload region A, a rough grinding region B, a finish grinding region C, and the load and unload region A by the rotation of the turntable 265.

The load and unload region A is a region where the wafer W is loaded onto and unloaded from the holding table 260. The rough grinding region B is a region where the back surface 12 of the wafer W held on the holding table 260 is rough ground by a rough grinding unit 270a. The finish grinding region C is a region where the back surface 12 of the wafer W held on the holding table 260 is finished by the finish grinding unit 270b.

The grinding unit 270 is disposed on the other end side of the base 210. The grinding unit 270 includes the rough grinding unit 270a for rough grinding the wafer W and the finish grinding unit 270b for finish grinding the wafer W. Since the rough grinding unit 270a and the finish grinding unit 270b have the same basic configuration, the rough grinding unit 270a will be mainly described here, and the finish grinding unit 270b will be denoted by the same reference numerals and the description thereof will be omitted.

A column 205 on the base 210 is provided with a lifting mechanism 271 that moves the rough grinding unit 270a toward and away from the holding table 260 in the Z-axis direction to feed the rough grinding unit 270a. The lifting mechanism 271 includes a pair of guide rails 272 disposed along the Z-axis direction. A flat lifting plate 273 is attached to the pair of guide rails 272 so as to be slidable along the guide rails 272.

A nut (not illustrated) is provided on a back surface of the lifting plate 273, and the nut is coupled to a ball screw 274 disposed along the Z-axis direction between the pair of guide rails 272. A pulse motor 275 that rotates the ball screw 274 is coupled to an end portion of the ball screw 274. When the ball screw 274 is rotated by the pulse motor 275, the lifting plate 273 moves in the Z-axis direction along the guide rails 272.

A housing 276 protruding from a front surface of the lifting plate 273 is fixed to the lifting plate 273. The housing 276 supports the rough grinding unit 270a. The rough grinding unit 270a is accommodated in the housing 276, and includes a cylindrical spindle 277 disposed substantially perpendicular to the holding surface of the holding table 260 and a rotational drive source (not illustrated) such as a motor that rotates the spindle 277 in a direction substantially parallel to the Z-axis direction. A disk-shaped wheel mount 278 is fixed to a lower end of the spindle 277, and a grinding wheel 279 is fixed to a lower end of the wheel mount 278.

The grinding wheel 279 includes an annular wheel base made of a metal material such as stainless steel and aluminum, and a plurality of grindstones annularly disposed on a lower surface of the wheel base. The grindstones contain a binder formed of ceramics, resin, a metal material, and the like, and numerous abrasive grains such as diamond dispersed and fixed in the binder.

The wafer W held on each holding table 260 is ground by the rough grinding unit 270a and the finish grinding unit 270b in this order. The wafer W ground by the finish grinding unit 270b is moved to the load and unload region A by the rotation of the turntable 265.

Then, the wafer W is unloaded from the holding table 260 located in the load and unload region A and transferred to the cleaning unit 280 by the unload unit 250.

The cleaning unit 280 cleans the ground wafer W transferred from the holding table 260 located in the load and unload region A, and removes grinding debris and the like. The cleaning unit 280 includes a spinner table 281 that rotates while supporting the wafer W, and a nozzle (not illustrated) that sprays a cleaning fluid onto the wafer W held by the spinner table 281. The wafer W cleaned by the cleaning unit 280 is unloaded from the spinner table 281 and loaded into the cassette C3 by the transfer unit 290 which will be described later. The spinner table 281 in the cleaning unit 280 is an example of a “support unit”.

The transfer unit 290 takes out the unground wafer W from the cassette C3 and transfers the wafer W to the alignment unit 230, and also takes out the ground wafer W from the cleaning unit 280 and transfers the wafer W to the cassette C3. The transfer unit 290 includes, for example, a U-shaped arm, and suctions and holds the wafer W by the arm 291 and transfers the wafer W.

The control unit 300 controls each of the above components of the processing device 200 to execute various types of processing. The control unit 300 is a computer including a controller 310 that performs various calculations, a storage unit 320 including a storage medium, and the like.

The storage unit 320 stores correlation information 320a with reference to FIGS. 6 to 8 described above. The correlation information 320a may be similar to the correlation information 120a in the embodiment described above. The controller 310 refers to the correlation information 320a and controls the direction of the wafer W when the wafer W is transferred to the cassette C3 such that the amount of deflection decreases when the wafer Wis accommodated in the cassette C3. Specifically, the controller 310 controls at least one of the holding table 260, the spinner table 281 in the cleaning unit 280, or the transfer unit 290 to control the direction of the wafer W when the wafer W is loaded into the cassette C3. That is, the controller 310 adjusts the direction of the wafer W at the timing of any processing in the processing device 200 such that the amount of deflection decreases when the wafer W is accommodated in the cassette C3. Even if the direction of the wafer W is adjusted at the timing of any processing, the direction of the wafer W may be shifted in the processing of transferring the wafer W. Therefore, in such a case, the direction of the wafer W may be adjusted by controlling a plurality of components among the holding table 260, the spinner table 281, and the transfer unit 290.

Although the above processing device 200 is a device having a grinding function by the grinding unit 270, the processing device 200 may be, for example, a processing device including a polishing unit that polishes the ground wafer W.

### Processing Method

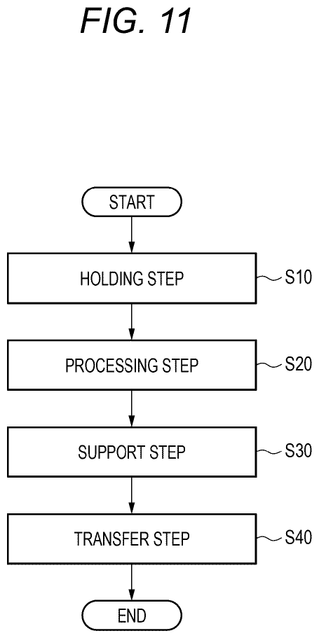

Next, a method for processing the workpiece will be described. FIG. 11 is a flowchart illustrating an example of the processing method. The processing method includes, as processing, a holding step S10, a processing step S20, a support step S30, and a transfer step S40. The processing of each step is executed by the controller 310.

In the holding step S10, the controller 310 holds the wafer W, which is the workpiece. That is, the wafer W is loaded onto the holding table 260 and held by the holding table 260.

In the processing step S20, the controller 310 processes the wafer W held in the holding step S10. That is, the rough grinding unit 270a and the finish grinding unit 270b perform grinding in this order.

In the support step S30, the controller 310 supports the wafer W ground in the processing step S20. That is, the ground wafer W is unloaded from the holding table 260, transferred to the cleaning unit 280, and supported by the spinner table 281.

In the transfer step S40, the controller 310 loads the wafer W supported in the support step S30 into the cassette C3 placed on the cassette table 220. That is, the wafer W is unloaded from the spinner table 281 and loaded into the cassette C3 by the transfer unit 290. At the time of loading, the controller 310 refers to the correlation information 320a in the storage unit 320, specifies a direction of the wafer W in which the amount of deflection of the wafer W decreases, and loads the wafer W into the cassette C3 such that the wafer W has the specified direction. Accordingly, it is possible to reduce the deflection of the wafer W when the wafer W is accommodated in the cassette C3.

Although the embodiments of the present disclosure have been described above with reference to the accompanying drawings, it is needless to say that the present disclosure is not limited to the embodiments. It is obvious that those skilled in the art may come up with various changes or modifications within the scope of the claims, and it is understood that these naturally fall within the technical scope of the present disclosure. In addition, components in the embodiments described above may be freely combined without departing from the gist of the disclosure.

For example, in the embodiment described above, as an example of the wafer W, a wafer subjected to TAIKO grinding has been described, but the wafer W is not limited to a wafer subjected to TAIKO grinding. That is, the wafer W may be a normal wafer in which the annular reinforcing portion 14 described above is not provided and the outer peripheral edge is substantially flat.

The transfer method and the processing method described in the above embodiment can be implemented by executing a control program prepared in advance by a computer. The control program is recorded in a computer-readable storage medium and executed by being read from the storage medium. The control program may be provided in a form stored in a non-transitory storage medium such as a flash memory, or may be provided via a network such as the Internet. The computer that executes the control program may be included in a processing device, may be included in an electronic device such as a smartphone, a tablet terminal, or a personal computer capable of communicating with the processing device, or may be included in a server device capable of communicating with the processing device and the electronic device.

The present specification describes at least the following matters. The components in parentheses correspond to those in the embodiment described above, but are not limited thereto.

(1) A transfer device (transfer device 1) including:
a cassette table (cassette table 30) on which a cassette (cassette C) capable of accommodating an object to be transferred (wafer W) is placed;
a support unit (support unit 50) configured to support the object to be transferred;
a transfer unit (transfer unit 40) configured to load the object to be transferred supported by the support unit into the cassette; and
a control unit (control unit 100) configured to control the support unit and the transfer unit, in which
the cassette includes a pair of side walls (side walls 32) facing each other, and a support portion (support portion 33) that is provided on inner side surfaces of the pair of side walls and supports an outer periphery of the object to be transferred,
the control unit includes
   a storage unit (storage unit 120) configured to store correlation information (correlation information 120a) indicating a correlation between information on a direction of the object to be transferred when the object to be transferred is supported by the support portion of the cassette and amount of deflection of the object to be transferred when the object to be transferred is supported by the support portion of the cassette, and
   a controller (controller 110) configured to control, based on the correlation information, the direction of the object to be transferred by at least one of the support unit or the transfer unit when the object to be transferred is loaded from the support unit into the cassette such that the amount of deflection of the object to be transferred decreases.

According to (1), based on the correlation information indicating the correlation between the information on the direction of the object to be transferred when the object to be transferred is supported by the support portion of the cassette and the amount of deflection when the object to be transferred is supported by the support portion, the direction of the object to be transferred is controlled such that the amount of deflection of the object to be transferred decreases. Therefore, it is possible to reduce the deflection of the object to be transferred in the cassette.

(2) The transfer device according to (1), in which
the information on the direction of the object to be transferred includes information on a direction of a crystal orientation of the object to be transferred.

According to (2), the direction of the crystal orientation affects the deflection of the object to be transferred. Therefore, by controlling the direction of the object to be transferred when the object to be transferred is accommodated in the cassette in consideration of the direction of the crystal orientation, it is possible to reduce the deflection of the object to be transferred in the cassette.

(3) The transfer device according to (1) or (2), in which
the information on the direction of the object to be transferred includes information on whether a grinding surface is an upper surface or a lower surface of the object to be transferred.

According to (3), the deflection of the object to be transferred may vary depending on whether the grinding surface of the object to be transferred is the upper surface or the lower surface. Therefore, by controlling the direction of the object to be transferred when the object to be transferred is accommodated in the cassette in consideration of the information on the direction of the grinding surface, it is possible to determine an appropriate direction of the object to be transferred in which the amount of deflection in the cassette decreases.

(4) The transfer device according to (1), in which
the object to be transferred includes a substrate and a sheet fixed to the substrate, and
the correlation information is information indicating a correlation between the information on the direction of the object to be transferred, sheet information on the sheet, and the amount of deflection.

According to (4), the amount of deflection of the object to be transferred may vary depending on the state of the sheet fixed to the substrate. Therefore, when the sheet information is included in the information indicating the correlation with the amount of deflection, it is possible to determine an appropriate direction of the object to be transferred in which the amount of deflection in the cassette decreases.

(5) The transfer device according to (4), in which
the sheet information includes information on an attachment direction in which the sheet is fixed to the substrate.

According to (5), the amount of deflection of the object to be transferred may vary depending on the attachment direction of the sheet. Therefore, when the attachment direction of the sheet is included in the sheet information, it is possible to determine an appropriate direction of the object to be transferred in which the amount of deflection in the cassette decreases.

(6) The transfer device according to (4) or (5), in which
the sheet information includes information on a draw-out direction (MD direction) which is a direction in which the sheet is drawn out during production of the sheet and/or information on an orthogonal direction (TD direction) orthogonal to the draw-out direction.

According to (6), the draw-out direction of the sheet fixed to the substrate and the orthogonal direction orthogonal to the draw-out direction may affect the amount of deflection of the object to be transferred. Therefore, when the information on the draw-out direction of the sheet and the orthogonal direction is included in the sheet information, it is possible to determine an appropriate direction of the object to be transferred in which the amount of deflection in the cassette decreases.

(7) A transfer method for loading an object to be transferred (wafer W) into a cassette (cassette C), the transfer method including:
a support step (support step S1) of supporting the object to be transferred; and
a transfer step (transfer step S2) of loading the object to be transferred supported in the support step into the cassette placed on a cassette table (cassette table 30), in which
in the transfer step, based on correlation information (correlation information 120a) indicating a correlation between information on a direction of the object to be transferred when the object to be transferred is supported by a support portion of the cassette and amount of deflection of the object to be transferred when the object to be transferred is supported by the support portion of the cassette, the object to be transferred is loaded into the cassette such that the amount of deflection of the object to be transferred decreases.

According to (7), based on the correlation information indicating the correlation between the information on the direction of the object to be transferred when the object to be transferred is supported by the support portion of the cassette and the amount of deflection when the object to be transferred is supported by the support portion, the direction of the object to be transferred is controlled such that the amount of deflection of the object to be transferred decreases. Therefore, it is possible to reduce the deflection of the object to be transferred in the cassette.

(8) A processing method including:
a holding step (holding step S10) of holding a workpiece (wafer W);
a processing step (processing step S20) of processing the workpiece held in the holding step;
a support step (support step S30) of supporting the workpiece processed in the processing step; and
a transfer step (transfer step S40) of loading the workpiece supported in the support step into a cassette (cassette C3) placed on a cassette table (cassette table 220), in which
in the transfer step, based on correlation information (correlation information 320a) indicating a correlation between information on a direction of the workpiece when the workpiece is supported by a support portion of the cassette and amount of deflection of the workpiece when the workpiece is supported by the support portion of the cassette, the workpiece is loaded into the cassette such that the amount of deflection of the workpiece decreases.

According to (8), based on the correlation information indicating the correlation between the information on the direction of the object to be transferred when the object to be transferred is supported by the support portion of the cassette and the amount of deflection when the object to be transferred is supported by the support portion, the direction of the object to be transferred is controlled such that the amount of deflection of the object to be transferred decreases. Therefore, it is possible to reduce the deflection of the object to be transferred in the cassette.

### REFERENCE SIGNS LIST

1 transfer device

30 cassette table

32 side wall

33 support portion

40 transfer unit

50 support unit

100 control unit

110 controller

120 storage unit

120a correlation information

220 cassette table

320a correlation information

C cassette

C3 cassette

W wafer (object to be transferred, workpiece)

S1 support step

S2 transfer step

S10 holding step

S20 processing step

S30 support step

S40 transfer step

What is claimed is:

1. A transfer device comprising:
a cassette table on which a cassette capable of accommodating an object to be transferred is placed;
a support unit configured to support the object to be transferred;
a transfer unit configured to load the object to be transferred supported by the support unit into the cassette; and
a control unit configured to control the support unit and the transfer unit, wherein
the cassette includes a pair of side walls facing each other, and a support portion that is provided on inner side surfaces of the pair of side walls and supports an outer periphery of the object to be transferred,
the control unit includes
a storage unit configured to store correlation information indicating a correlation between information on a direction of the object to be transferred when the object to be transferred is supported by the support portion of the cassette and amount of deflection of the object to be transferred when the object to be transferred is supported by the support portion of the cassette, and
a controller configured to control, based on the correlation information, the direction of the object to be transferred by at least one of the support unit or the transfer unit when the object to be transferred is loaded from the support unit into the cassette such that the amount of deflection of the object to be transferred decreases.

2. The transfer device according to claim 1, wherein
the information on the direction of the object to be transferred includes information on a direction of a crystal orientation of the object to be transferred.

3. The transfer device according to claim 1, wherein
the information on the direction of the object to be transferred includes information on whether a grinding surface is an upper surface or a lower surface of the object to be transferred.

4. The transfer device according to claim 2, wherein
the information on the direction of the object to be transferred includes information on whether a grinding surface is an upper surface or a lower surface of the object to be transferred.

5. The transfer device according to claim 1, wherein
the object to be transferred includes a substrate and a sheet fixed to the substrate, and
the correlation information is information indicating a correlation between the information on the direction of the object to be transferred, sheet information on the sheet, and the amount of deflection.

6. The transfer device according to claim 5, wherein
the sheet information includes information on an attachment direction in which the sheet is fixed to the substrate.

7. The transfer device according to claim 5, wherein
the sheet information includes at least one of: information on a draw-out direction which is a direction in which the sheet is drawn out during production of the sheet; or information on an orthogonal direction orthogonal to the draw-out direction.

8. The transfer device according to claim 6, wherein
the sheet information includes at least one of: information on a draw-out direction which is a direction in which the sheet is drawn out during production of the sheet; or information on an orthogonal direction orthogonal to the draw-out direction.

9. A transfer method for loading an object to be transferred into a cassette, the transfer method comprising:
supporting the object to be transferred; and
loading the object to be transferred supported in the supporting into the cassette placed on a cassette table, wherein
in the loading, based on correlation information indicating a correlation between information on a direction of the object to be transferred when the object to be transferred is supported by a support portion of the cassette and amount of deflection of the object to be transferred when the object to be transferred is supported by the support portion of the cassette, the object to be transferred is loaded into the cassette such that the amount of deflection of the object to be transferred decreases.

10. A processing method comprising:
holding a workpiece;
processing the workpiece held in the holding;
supporting the workpiece processed in the processing; and
loading the workpiece supported in the supporting into a cassette placed on a cassette table, wherein
in the loading, based on correlation information indicating a correlation between information on a direction of the workpiece when the workpiece is supported by a support portion of the cassette and amount of deflection of the workpiece when the workpiece is supported by the support portion of the cassette, the workpiece is loaded into the cassette such that the amount of deflection of the workpiece decreases.
